(19) United States
(12) Patent Application Publication
(10) Pub. No.: US 2026/0239654 A1
(43) Pub. Date: Aug. 13, 2026

(54) METHOD AND SYSTEM FOR VERTICAL GAN JFET WITH ISOLATED BACK BARRIER

(71) Applicant: Alithia Power Inc., Raleigh, NC (US)

(72) Inventors: Cristofer Ugolini, Raleigh, NC (US); Allen Hanson, Cary, NC (US)

(73) Assignee: Alithia Power Inc., Raleigh, NC (US)

(21) Appl. No.: 19/539,695

(22) Filed: Feb. 13, 2026

Related U.S. Application Data
(60) Provisional application No. 63/758,101, filed on Feb. 13, 2025.
(60) Provisional application No. 63/898,973, filed on Oct. 14, 2025.

(51) Int. Cl. H10D 30/47

(52) U.S. Cl. CPC H10D 30/4755

(57) ABSTRACT

Techniques are disclosed for a vertical GaN junction field effect transistor (JFET). The JFET can include a substrate, a drift layer coupled to the substrate, a channel layer coupled to the drift layer at the interface, a gate layer coupled to the channel layer, and source, gate, and drain contacts. The JFET can also include a barrier region formed within the drift layer at a location below the interface of the drift layer. The barrier region can define a lateral channel of the JFET extending between the barrier region and the gate.

### CROSS REFERENCE TO RELATED APPLICATIONS

The present application claims the benefit of U.S. Provisional Patent App. No. 63/758,101, entitled “METHODS AND SYSTEM FOR VERTICAL GAN JFET WITH ISOLATED BACK BARRIER,” filed on Feb. 13, 2025, and U.S. Provisional Patent App. No. 63/898,973, entitled “METHOD AND SYSTEM FOR VERTICAL GAN FET WITH EPITAXIAL BACK BARRIER,” filed on Oct. 14, 2025, the entire contents of which are herein incorporated by reference in their entirety.

### BACKGROUND OF THE INVENTION

Gallium nitride (GaN) is a wide bandgap semiconductor that is used in numerous applications. GaN's wide bandgap allows GaN devices to operate at higher voltages, temperature, and frequencies, making GaN devices suitable for high-power applications. In addition, the high electron mobility and saturation velocity of GaN make GaN an excellent material for high-power transistors used in radio frequency (RF) and microwave applications and for power conversion.

Despite the progress made in the field of GaN devices, there is a need in the art for improved GaN-based semiconductor devices and improved methods for fabricating the same.

### BRIEF DESCRIPTION OF THE DRAWINGS

FIG. 1 is a simplified flowchart illustrating a method for making a GaN drift layer with a barrier region, according to some embodiments.

FIG. 2 is a diagram illustrating a GaN drift layer with a barrier region, according to some embodiments.

FIG. 3 is a simplified flowchart illustrating a method for making a vertical GaN junction field effect transistor (JFET) having a planar channel and an isolated barrier region, according to some embodiments.

FIGS. 4-7 are diagrams illustrating cross-section views of the vertical GaN JFET at various steps of the method of FIG. 3.

FIG. 8 is a simplified flowchart illustrating a method for making a vertical GaN JFET having a vertical side wall channel and an isolated barrier region, according to some embodiments.

FIGS. 9-13 are diagrams illustrating cross-section views of the vertical GaN JFET at various steps of the method of FIG. 8.

FIG. 14 is a simplified flowchart illustrating a method for making a GaN drift layer and an epitaxial barrier layer, according to some embodiments.

FIG. 15 is a diagram illustrating a GaN drift layer and an epitaxial barrier layer, according to some embodiments.

FIG. 16 is a diagram illustrating a cross section view of a vertical GaN junction field effect transistor (JFET) having an epitaxial barrier layer, according to some embodiments.

FIG. 17 is a simplified flowchart illustrating a method for making a vertical GaN JFET having a vertical side wall trench and an epitaxial barrier layer, according to some embodiments.

FIGS. 18-21 are diagrams illustrating cross-section views of the vertical GaN JFET at various steps of the method of FIG. 17.

### DETAILED DESCRIPTION OF SPECIFIC EMBODIMENTS

A driving force for developments in power electronics is the further miniaturization of device architecture while retaining manufacturability. For GaN devices, growth of doped GaN layers on sub-micron structures like vertical fins can pose challenges for all but the most sophisticated foundries. For such vertical structures, which can be as small as 200 nm across, a high-quality GaN regrowth layer can be difficult to achieve. For devices like FETs, the growth layers may be used to form the channels critical for correct operation. Rather than controlling for the growth of GaN layers on nano-scale vertical structures, the embodiments described herein provide a novel way to use an implanted barrier region within a drift layer using planar oriented device layers. The implanted barrier region can be used to restrict charge carrier flow in the channel similar to a fin structure, but without the complex manufacturing techniques used in 3D finned designs. Additional embodiments include a barrier layer that is epitaxially grown on a drift layer in a planar orientation. The control of the dimensions of the epitaxially grown barrier layer allows for greater control over the length of a channel formed via lithography and subsequent regrowth of doped GaN layers. This greater control allows for reduced lithography requirements when compared to conventional e-mode FinFETs having sub-micron feature sizes. More particularly, embodiments of the present invention include two new JFET structures, and corresponding methods, that are manufactured using an isolated barrier region that is formed in a planar orientation within the drift layer of a substrate as well as a new FET structure and corresponding method using a barrier layer that is formed epitaxially in a planar orientation on the drift layer of a substrate..

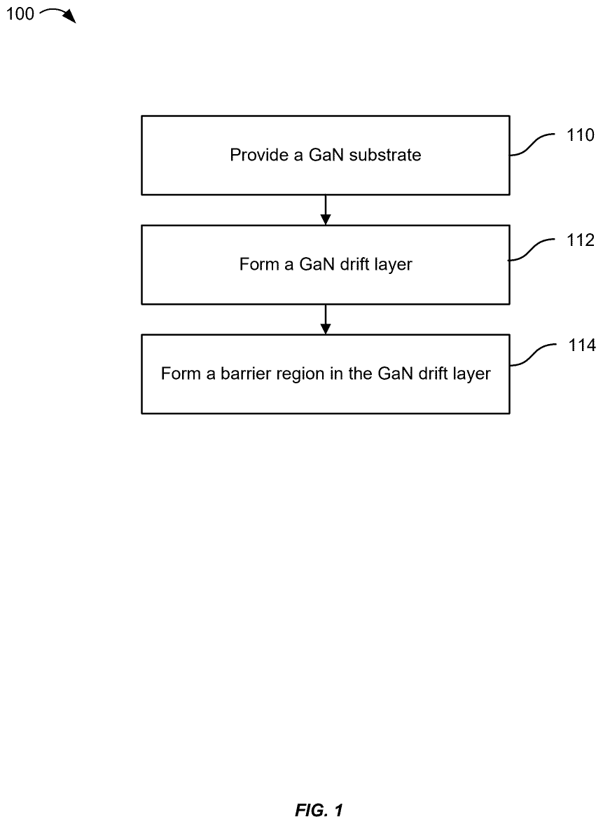

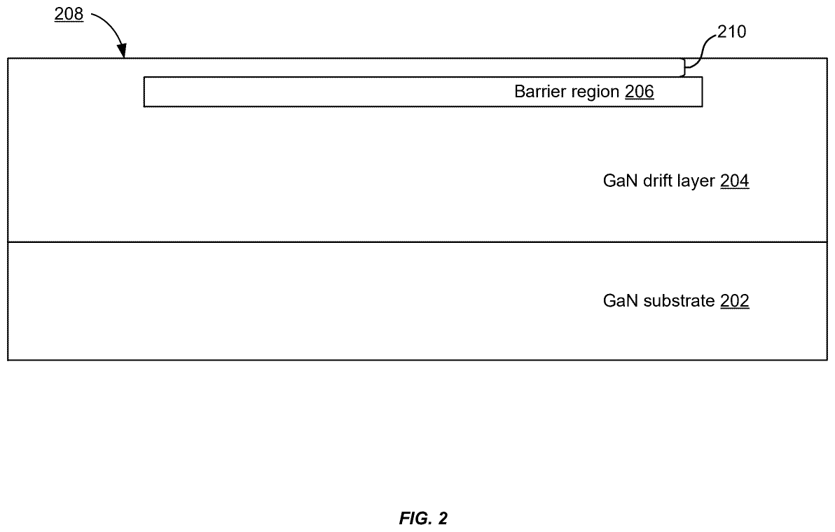

FIG. 1 is a simplified flowchart illustrating a method 100 for making a GaN drift layer with a barrier region, according to some embodiments. FIG. 2 is a diagram illustrating a GaN drift layer 204 with a barrier region 206, according to some embodiments. The GaN layers of FIG. 2 may be formed according to the method 100 of FIG. 1.

The method 100 includes providing (110) a substrate. In typical embodiments, the substrate can be a GaN substrate 202. The GaN substrate 202 may be grown using a suitable growth process. The GaN substrate 202 may be an N-type GaN substrate in some embodiments. The GaN substrate 202 may be relatively thick, about 450 μm, but the thickness can depend on the size of the wafer. For example, a GaN substrate 202 of 100 mm (~4 in) may have a thickness of about 450 μm, while a GaN substrate 202 of 150 mm (~6 in) may have a thickness of about 550 μm. The GaN substrate 202 may exhibit a resistivity of about 12 mΩ-cm² in certain embodiments.

The method 100 also includes forming (112) a drift layer on the GaN substrate 202. The drift layer may also be a GaN drift layer 204. The GaN drift layer 204 may be epitaxially grown on the GaN substrate 202. The GaN drift layer 204 can be doped. The doping can be either n-type or p-type, according to some embodiments. The doping concentration of the GaN drift layer 204 can be about 1×10¹⁶ cm⁻³ or less, depending on the breakdown voltage requirements of the device In some embodiments, the GaN drift layer 204 can be formed using hydride vapor phase epitaxy (HVPE) process. The deposited GaN drift layer 204 may be about 10 μm to 25 μm thick.

The method 100 can also include forming (114) a barrier region 206 within the drift region 204. As shown in FIG. 2, the barrier region 206 can be formed between the surface 208 of the epitaxially grown GaN drift layer 204 and the GaN substrate 202. Because, the drift region 204 is grown on the substrate 202, the barrier region 206 can be referred to as being located “below” the surface 208. The depth 210 extending from the surface 208 toward the substrate, also referred to as the depth below the surface 208, can be controlled using the implantation process parameters. By forming the barrier region 206 below the surface 208, the quality of the surface 208 of the GaN drift layer 204 can be preserved for subsequent growth process on the GaN drift layer 204. In some embodiments, the depth 210 can be 10-20 Å (1-2 nm) below the surface of the GaN drift layer 204. In some embodiments, the depth 210 may be 0, so that the barrier region 206 extends to the surface of the GaN drift layer 204. In general, the amount of GaN drift layer material between the barrier region 206 and the surface 208 of the GaN drift layer 204 (e.g., the depth 210) should be minimized to limit the amount of drift layer material that can provide a current leakage path outside of the channel region of device layers formed on the GaN drift layer 204, while still providing a suitable (e.g., undamaged) surface 208 for subsequent growth processes.

The barrier region 206 can be formed using ion implantation. The ion implantation process can form dislocations in the crystal structure of the GaN drift layer 204 within the barrier region 206. The implanted ions and/or the associated crystal dislocations can form the barrier region 206 with significantly higher resistivity than the surrounding GaN drift layer 204, allowing the barrier region 206 to withstand significant voltage difference across the source/drain of a JFET. The ions used for the implantation process can be argon, nitrogen, hydrogen, helium, fluorine, magnesium oxygen, zinc, iron, krypton, or other suitable ion, and can be chosen according to parameters including the resulting condition of the surface 208, the presence/absence of protective layers on the surface 208 during ion implantation, and/or controlling the depth 210 of the barrier region 206. The lateral extent of the barrier region 206 can be controlled by disposing photoresist on the surface 208 during the ion implantation process.

The barrier region 206 can be characterized by the following properties. The barrier region 206 can have a relatively high resistivity. For example, the barrier region 206 can be characterized by a resistivity of between about 10⁸ Ω/sq to about 10¹² Ω/sq. The barrier region 206 can remain relatively stable within its resistivity range during subsequent processing steps. The barrier region 206 can withstand an applied voltage (e.g., a stand-off voltage) in a stable manner. The barrier region 206 should not adversely impact quality of subsequent epitaxial growth and not introduce deep level charge carrier traps that can inhibit dispersion characteristics of the device.

By forming the barrier region 206 in the GaN drift layer 204, several advantages are achieved. First, the high resistivity barrier region 206 effectively serves to isolate the channel and source access regions from the drift regions of the device. Consequently, greater control over the channel dimensions and resistance can be achieved, which can be finely adjusted through the layer thicknesses and doping levels of the regrowth regions disposed on the GaN drift layer 204. Because vertical JFETs typically require stringent regulation of threshold voltage, the improved control of the channel using the implanted barrier region 206 can allow for the production of such devices. Furthermore, the barrier region 206 can be implemented in either patterned or non-patterned configurations, enabling use of this approach to realize both planar and side wall channel configurations. These configurations can result in device topologies with relaxed lateral dimension requirements, as well as relaxed lithography and etch requirement while also improving the operating parameters of the JFET.

In addition, the fabrication of the barrier region 206 is suitable for both enhancement mode (e-mode) and depletion mode (d-mode) devices. If the channel conductivity is such that meaningful current flows from source to drain at zero (or slightly positive) gate bias, the device is d-mode. This mode is often referred to as “normally-on.” If the channel conductivity is such that no meaningful current flows from the source to drain at zero gate bias, the device is considered e-mode. This mode is often referred to as “normally-off.” Devices of either mode type can be achieved through judicious choice of doping levels and channel layer dimensions. A JFET is a common high-power transistor design that opens or closes the channel using the depletion region generated at the interface of an n-type and p-type material. A depletion region in a PN junction is a narrow area where mobile charge carriers (electrons and holes) have diffused away, leaving behind a region with only fixed ionized donor and acceptor atoms, creating an electric field across the junction. Essentially, it's a region depleted of free charge carriers due to diffusion of charges across the junction. As described below, the implanted barrier region 206 allows for improved control of the channel region during fabrication of both planar and vertical side wall JFET devices,

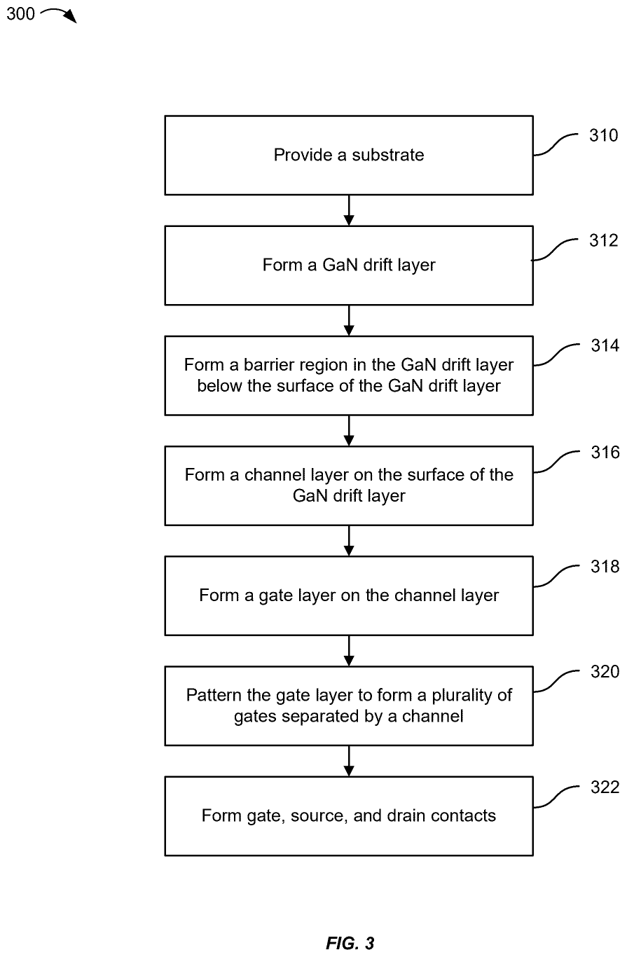

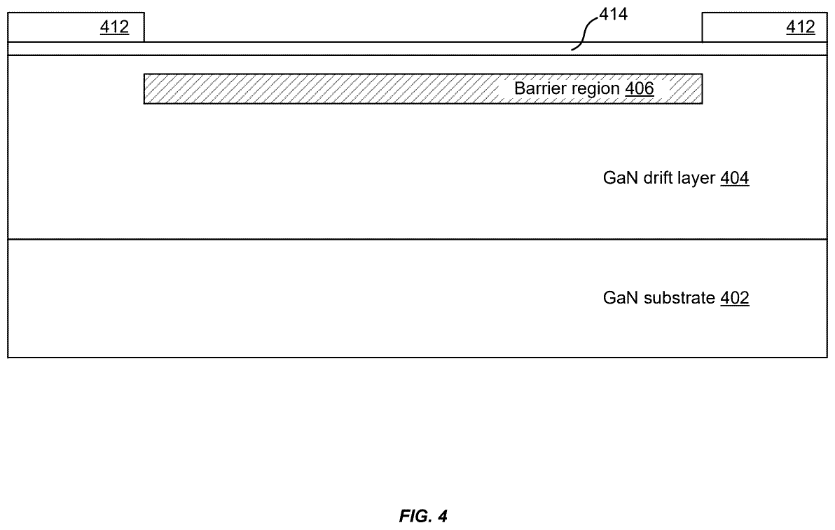

FIG. 3 is a simplified flowchart illustrating a method 300 for making a vertical GaN junction field effect transistor (JFET) having a planar channel and an isolated barrier region, according to some embodiments. FIGS. 4-7 are diagrams illustrating cross-section views of the vertical GaN JFET at various steps of the method 300 of FIG. 3.

The method 300 can include providing a substrate (310). As shown in FIG. 4, the substrate may be a GaN substrate 402, which may be an example of the GaN substrate 202 described above with respect to FIG. 2. The method 300 can also include forming a GaN drift layer on the substrate (312) and forming a barrier region in the GaN drift layer (314). The GaN drift layer 404 may be an example of GaN drift layer 204 of FIG. 2.

In some embodiments, a protective layer 414 can be disposed on the surface of GaN drift layer 404. The protective layer 414 may be a layer of silicon dioxide, another silicon oxide, silicon nitride (SiNₓ), titanium nitride (TiN), or other suitable material to provide protection to the epitaxially grown GaN drift layer 404 during the formation of the barrier region 406. For example, the GaN substrate 402 and GaN drift layer 404 may be transported to a system for ion implantation of the barrier region 406, so the protective layer 414 can provide protection to the surface during the transportation and implantation process. In some embodiments, the thickness of the protective layer 414 can be used to help control the depth (location) of the barrier region 406. For example, the protective layer 414 may reduce the ion penetration depth, resulting in a barrier region 406 formed close to the surface of the GaN drift layer 404 while still preserving the quality of the surface for subsequent regrowth processes.

In some embodiments, photoresist 412 can be provided on the surface of the protective layer 414. The photoresist 412 can be used to control the lateral extent of the barrier region 406 by blocking ion implantation beneath the photoresist 412. Such lateral control can be used to create isolated barrier regions for separate devices on a single GaN substrate 402. In some embodiments without the protective layer 414, the photoresist 412 may be disposed directly on the surface of the GaN drift layer 404.

In some embodiments, the protective layer 414 can support the formation of fiducials or other edge marks and/or alignment marks. These markings can be formed via etching into the protective layer. The alignment marks can be used to identify the lateral extent of the barrier region 406 in embodiments where the photoresist 412 is used to constrain the lateral extent of the barrier region 406. Such markings may be beneficial since the barrier region 406 may be below the surface of the GaN drift layer 404 and may not be visible during subsequent processing.

Once the barrier region 406 has been formed, the protective layer 414 and the photoresist 412 can be removed from the GaN drift layer 404 using suitable wet or dry chemistry. The surface of the GaN drift layer 404 can be cleaned and prepped using suitable solvents (e.g., tetramethylammonium hydroxide, piranha solvent).

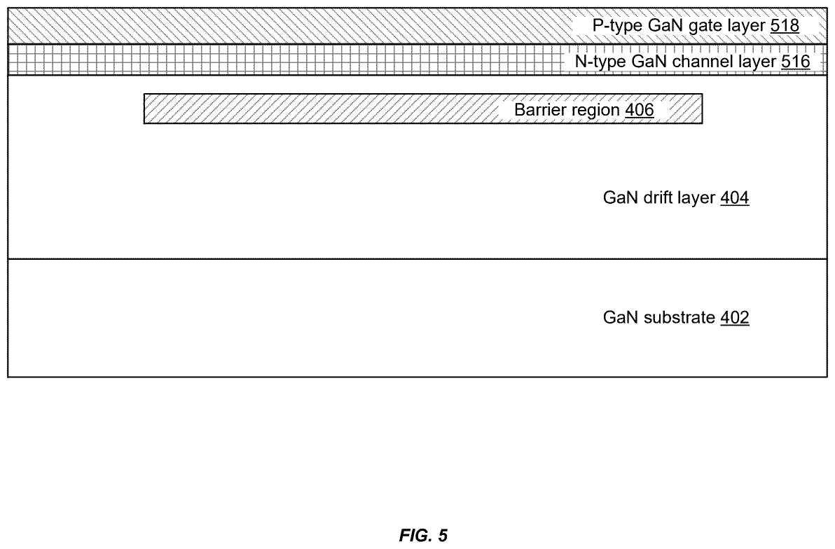

The method 300 can also include forming a channel layer on the surface of the GaN drift layer (316). Referring now to FIG. 5, the channel layer can be an n-type GaN channel layer 516. The GaN channel layer 516 can be moderately doped. For example, the GaN channel layer 516 can have a dopant concentration of 1×10¹⁶ cm⁻³. In some examples, the dopant concentration may be between about 1×10¹⁶ cm⁻³ and 1×10¹⁸ cm⁻³. The GaN channel layer 516 thickness can be about 200 nm, in an example. In some examples the GaN channel layer 516 can have a thickness of about 100 nm to about 500 nm. The doping concentration and the thickness can be controlled (in conjunction with the doping concentration and thickness of the GaN gate layer 518) so that the channel region of the JFET operates correctly (e.g., fully depleted of charge carriers at no applied gate potential).

The method 300 can also include forming a gate layer on the channel layer (318). The gate layer may be a highly doped p-type GaN gate layer 518. The GaN gate layer 518 can have a dopant concentration of about 1×10¹⁹ cm⁻³, in an example. The GaN gate layer 518 can have a thickness of 500 nm, in an example. As with the GaN channel layer 516, the doping and thickness of the GaN gate layer 518 can be controlled to support the designed operation of the JFET.

The GaN channel layer 516 and the GaN gate layer 518 may be formed using molecular beam epitaxy (MBE) or metalorganic chemical vapor deposition (MOCVD). Advantages of using MBE to grow the GaN channel layer 516 and/or the GaN gate layer 518 include that the lower temperatures of the MBE process (less than 800° C.) can preserve the high resistive properties of the barrier region 406.

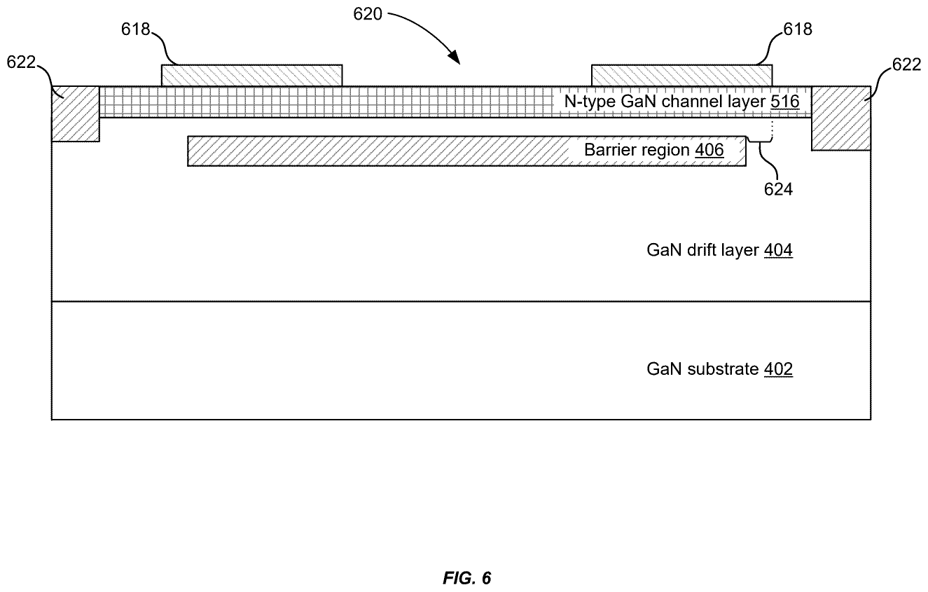

The method 300 can also include patterning the gate layer (e.g., GaN gate layer 518) to form a plurality of gates (320). Referring now to FIG. 6, each gate structure of the plurality of gates 618 can be separated by a channel 620. Patterning the GaN gate layer 518 to form the plurality of gates 618 can include etching the GaN gate layer 518 to remove the GaN gate layer 518 down to the GaN channel layer 516. The etching may be performed in an inductively coupled plasma (ICP) dry etching process. Removing GaN gate layer 518 to form the plurality of gates 618 can improve gate parasitic capacitance by limiting the lateral extent of the p-type GaN gate layer material.

In some embodiments, an etch stop can be disposed between the GaN channel layer 516 and the GaN gate layer 518 during the growth processes of those layers. The etch stop can preserve the well-controlled thickness of the GaN channel layer 516 that was formed first, particularly in the source access and contact regions of the device. After patterning the GaN gate layer 518, the etch stop can be removed from the exposed regions of the GaN channel layer 516. The presence of an etch stop between the gate structures and the GaN channel layer 516 may not negatively impact the performance of the resulting JFET since no gate current should flow through the gate structure.

In some embodiments, the plurality of gate structures 618 can be formed to extend laterally past the edge of the barrier region 406. The distance 624 of the lateral extension of the gate structures (e.g., the patterned GaN gate layer 518) may be about 0.1 μm to about 10 μm. The overlap distance 624 can be chosen to ensure that the gate structure 618 fully extend over the barrier region 406 to improve the formation of the channel region via the applied gate potential during operation of the JFET. The distance 624 can also compensate for manufacturing tolerances in the gate structures 618 during lithography and etching. For example, the distance 624 can reduce the variability of the on-resistance brought about by process variations in lithography alignment. The amount of lateral extension may be a design parameter chosen to improve drain current distribution and hence the nominal on-resistance of the device. In some examples, the distance 624 may extend all the way to adjacent cells.

In some embodiments, additional structures can be added to define individual devices. As shown in FIG. 6, additional isolation implants 622 can be added (e.g., using ion implantation) to separate the GaN channel layer 516 from the channel layers of adjacent devices on the GaN substrate 402. Isolating the GaN channel layer 516 can prevent current flow from device to device while also promoting current spreading within the source to drain current path of the given JFET.

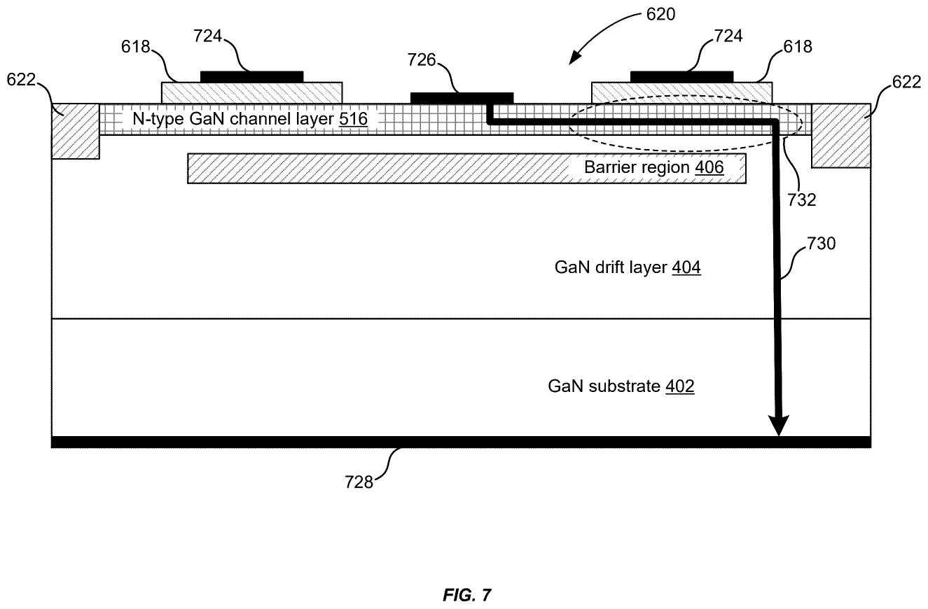

The method 300 can also include forming gate, source, and drain contacts (322). Referring now to FIG. 7, gate contacts 724 can be formed on the plurality of gate structures 618. A source contact 726 can be formed in the channel 620 on the surface of the GaN channel layer 516. A drain contact 728 can be formed on the backside of the GaN substrate 402 (forming a vertical JFET). The arrangement of source contact 726 and drain contact 728 on the GaN substrate 402 results in a current path 730 vertically through the GaN drift layer 404 as shown (resulting in a vertical JFET device). However, the channel 732 formed during operation of the JFET by the application of a gate potential extends “laterally” (e.g., horizontally) between the barrier region 406 and the gate 618.

The source, gate, and drain contacts can be ohmic contacts. In some embodiments, the ohmic contacts are formed by a metal deposition process. The ohmic contacts for the gate contacts 724, the source contact 726, and the drain contact 728 can include a variety of different metals and alloys used to connect to the n-type and p-type GaN material. When a negative voltage is applied between the gate contacts 724 and the source contact 726, the depletion region extends into the n-type GaN channel layer 516 connected to the source contact 726.

In some embodiments, the formation of the gate contacts 724, the source contact 726, and the drain contact 728 can include one or more annealing processes. The annealing process can include subjecting the vertical JFET to relatively high temperatures, up to 950° C. The annealing process may not affect the resistivity of the barrier region 406. In some examples, the resistivity properties of the barrier region 406 may improve after the annealing processes. In some embodiments, thermal annealing may be performed as a separate process after the formation of the barrier region 406, after the formation of either of the GaN channel layer 516 and GaN gate layer 518, or after the formation of the ohmic contacts.

In some embodiments, an encapsulation layer can be added to enclose the gate contacts 724 to isolate the gate contacts 724 from the source contact 726. The source contact 726 can be accessed by a source via provided by an interconnect metallization layer formed over the gate encapsulation, with access to the gate contacts 724 preserved in the direction into/out from the view shown in FIG. 7. The encapsulation layer may be a silicon nitride layer deposited using a plasma enhanced chemical vapor deposition process (PECVD). The metallization can be a gold plating layer.

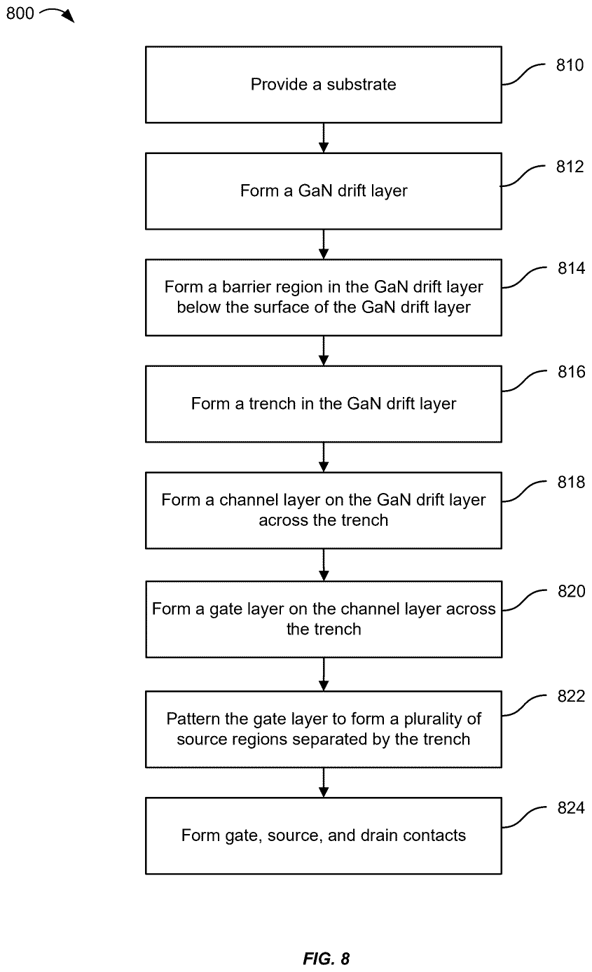

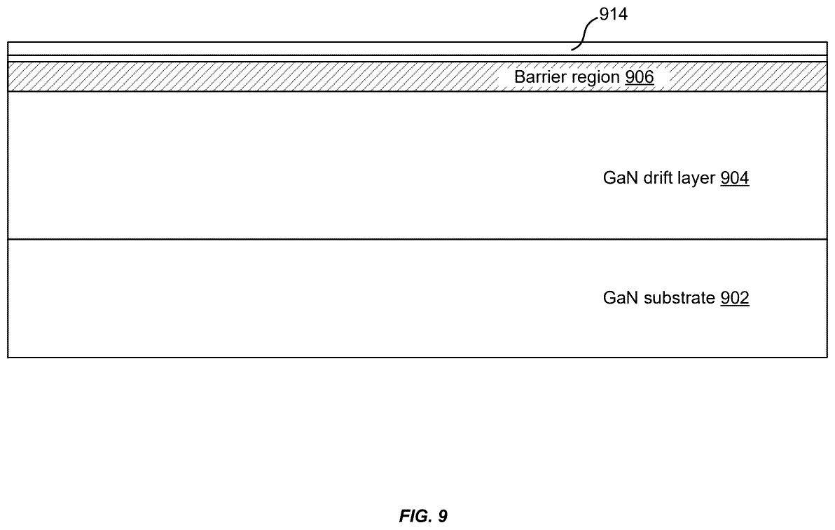

FIG. 8 is a simplified flowchart illustrating a method 800 for making a vertical GaN JFET having vertical side wall channel and an isolated barrier region, according to some embodiments. FIGS. 9-13 are diagrams illustrating cross-section views of the vertical GaN JFET at various steps of the method 800 of FIG. 8.

The method 800 can include providing a substrate (810), forming a drift layer GaN (812), and forming a barrier region in the drift layer (814). The operations 810-814 may be similar to those described above with respect to FIG. 3. Referring to FIG. 9, the substrate may be a GaN substrate 902, the drift layer may be a GaN drift layer 904, and the barrier region 906 may be a region of implant-damaged drift layer material. The GaN substrate 902 may be an example of the GaN substrate 202 described above with respect to FIG. 2. The GaN drift layer 904 may be an example of GaN drift layer 204 of FIG. 2. The barrier region 906 may be an example of barrier region 206 of FIG. 2.

In contrast to the embodiment of FIGS. 3-7, the structure of the vertical JFET with vertical side wall channel can allow for the formation of the barrier region 906 extending over the entirety of the GaN drift layer 904. The subsequent processing steps can isolate different devices constructed on the GaN drift layer 904 and GaN substrate 902 by, for example, forming implantation regions on the edges of the devices. By forming the barrier region 906 over the entirety of the GaN drift layer 904, processing steps including application of photoresist to control the lateral extent of the barrier region and the formation of fiducials to indicate the position of the sub-surface barrier region can be omitted, simplifying the fabrication process.

In some embodiments, a protective layer 914 can be disposed on the surface of GaN drift layer 904. The protective layer 914 may be similar to protective layer 414 described above with respect to FIG. 4, and may be a layer of silicon dioxide, another silicon oxide, silicon nitride (SiN_{X}), titanium nitride (TiN), or other suitable material to provide protection to the epitaxially grown GaN drift layer 904 during the formation of the barrier region 906. For example, the GaN substrate 902 and GaN drift layer 904 may be transported to a system for ion implantation of the barrier region 906, so the protective layer 914 can provide protection to the surface during the transportation and implantation process. In some embodiments, the thickness of the protective layer 914 can be used to help control the depth (location) of the barrier region 906. For example, the protective layer 914 may reduce the ion penetration depth, resulting in a barrier region 906 formed close to the surface of the GaN drift layer 904 while still preserving the quality of the surface for subsequent regrowth processes.

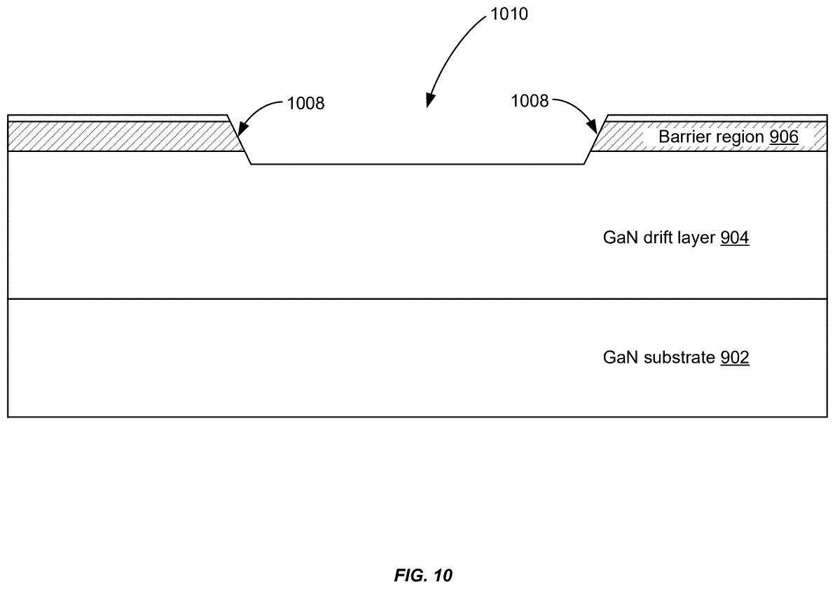

The method 800 can also include forming a trench in the drift layer (816). Referring to FIG. 10, the trench 1010 may be formed into the GaN drift layer 904 and extending below the barrier region 906. The trench 1010 may be formed by an etching process like ICP. The trench 1010 can have vertical side walls 1008 that define the sides of the trench 1010. As shown in FIG. 10, the vertical side walls 1008 may be sloped. The angle of the slope of the vertical side walls 1008 may be varied based on the design of the JFET. In some embodiments, the vertical side walls 1008 may be vertical or nearly vertical.

The formation of the trench 1010 may expose the barrier region 906 at the vertical side walls 1008. The trench 1010 may be etched deeper into the GaN drift layer 904 than the vertical extent of the barrier region 906, so that the region in the middle of the trench is exposed material of the GaN drift layer 904 and not material of the barrier region 906. The trench 1010 can separate the surface of the GaN drift region 904 into two lateral regions on either side of the trench.

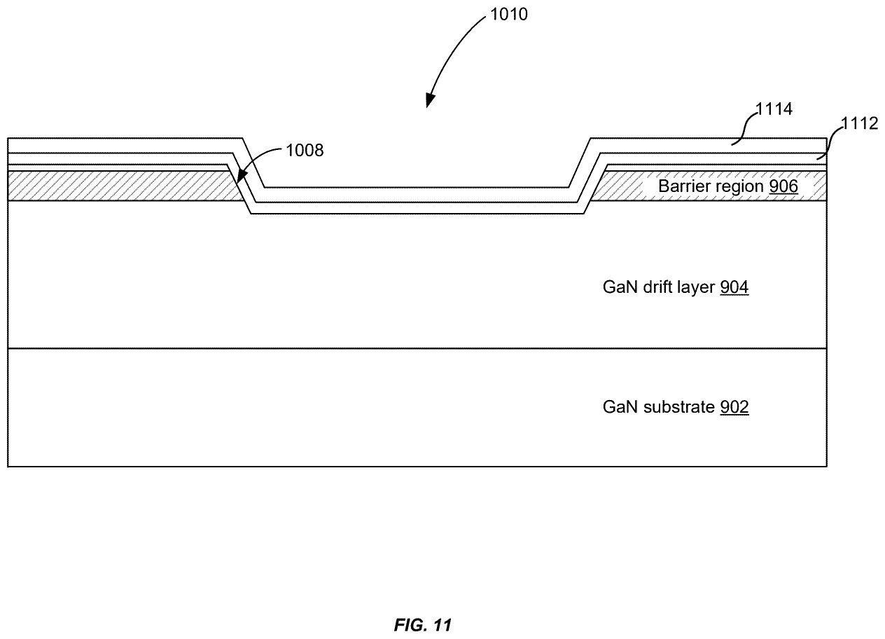

The method 800 can also include forming a channel layer (818) and forming a gate layer (820) on the trench and GaN drift layer 904. As shown in FIG. 11, the channel layer may be an n-type GaN channel layer 1112 and the gate layer may be a p-type GaN gate layer 1114. Both the GaN channel layer 1112 and the GaN gate layer 1114 can be formed extending from the lateral regions into the trench, including formation on the vertical side walls 1008.

The GaN channel layer 1112 and the GaN gate layer 1114 may be similar to the GaN channel layer 516 and GaN gate layer 518 described above with respect to FIGS. 5-7. The GaN channel layer 1112 can be moderately doped. For example, the GaN channel layer 1112 can have a dopant concentration of 1×10¹⁶ cm⁻³. In some examples, the dopant concentration may be between about 1×10¹⁶ cm⁻³ and 1×10¹⁸ cm⁻³. The GaN channel layer 1112 thickness can be about 200 nm, in an example. In some examples the GaN channel layer 1112 can have a thickness of about 100 nm to about 500 nm. The GaN channel layer 1112 thickness can be about 200 nm, in an example. The doping concentration and the thickness can be controlled (in conjunction with the doping concentration and thickness of the GaN gate layer 1114) so that the channel region of the JFET operates correctly (e.g., fully depleted of charge carriers at gate potentials less than a threshold voltage). The gate layer may be a highly doped p-type GaN gate layer 1114. The GaN gate layer 1114 can have a dopant concentration of about 1×10¹⁹ cm⁻³, in an example. The GaN gate layer 1114 can have a thickness of 500 nm, in an example. As with the GaN channel layer 1112, the doping and thickness of the GaN gate layer 1114 can be controlled to support the designed operation of the JFET. The GaN channel layer 1112 and the GaN gate layer 1114 may be formed using molecular beam epitaxy (MBE) or metalorganic chemical vapor deposition (MOCVD).

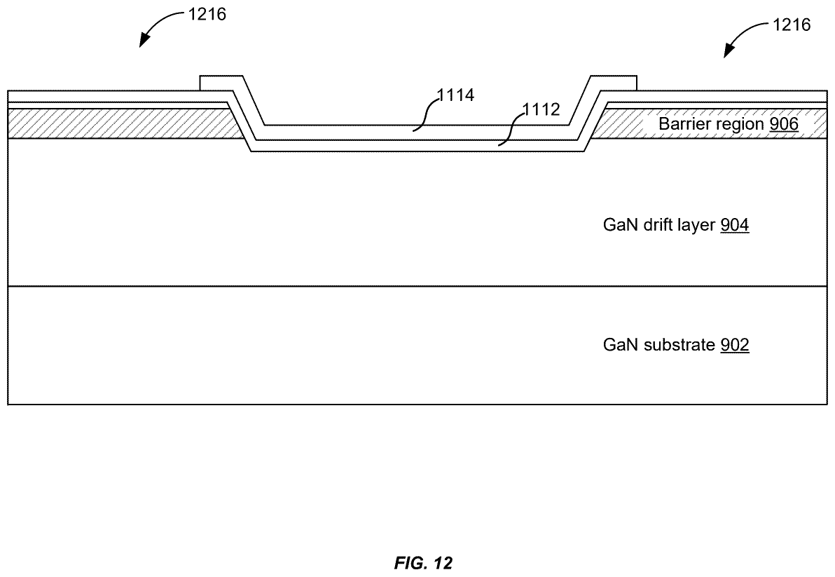

The method 800 can also include patterning the gate layer to form a plurality of source regions (822). Referring to FIG. 12, the plurality of source regions 1216 can be formed on each side of the trench 1010. Patterning the GaN gate layer 1114 to form the plurality of source regions 1216 can include etching the GaN gate layer 1114 to remove the GaN gate layer 1114 down to the GaN channel layer 1112. The etching may be an inductively coupled plasma (ICP) dry etching process. As with the patterning operations described above with respect to the embodiments of FIGS. 3-7, in some embodiments, an etch stop can be disposed between the GaN channel layer 1112 and the GaN gate layer 1114 during the growth processes of those layers.

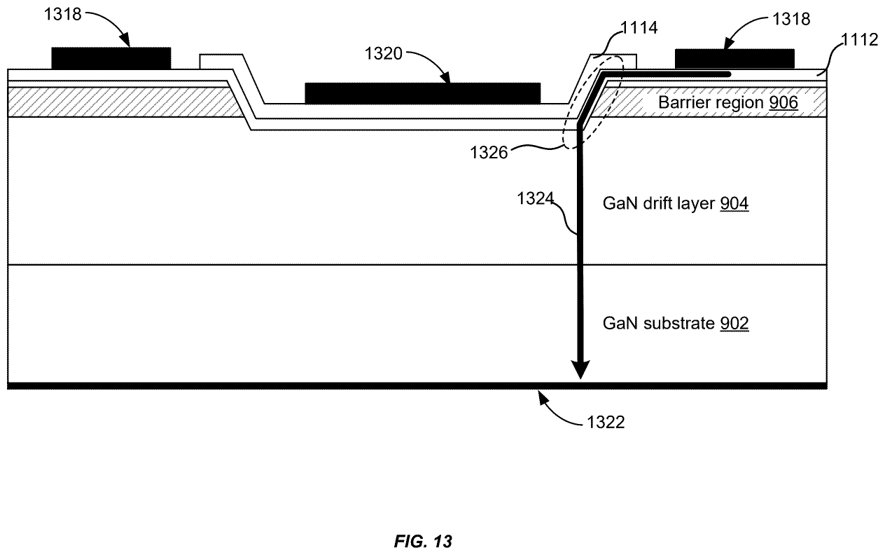

The method 800 can also include forming gate, source, and drain contacts (824). Referring now to FIG. 13, gate contact 1320 can be formed in the trench 1010 on the GaN gate layer 1114. A plurality of source contacts 1318 can be formed in the source regions 1216 on the surface of the GaN channel layer 1112. A drain contact 1322 can be formed on the backside of the GaN substrate 902 (forming a vertical JFET). The arrangement of source contacts 1318 and drain contact 1322 on the GaN substrate 902 results in a current path 1324 vertically through the GaN drift layer 904 as shown, thereby forming a vertical JFET. In this embodiment, the channel 1326 is formed along the vertical side wall, and may be vertical (or nearly vertical), to contrast with the horizontal (“lateral”) channel 732 of FIG. 7.

The source, gate, and drain contacts can be ohmic contacts. In some embodiments, the ohmic contacts are formed by a metal deposition process. The ohmic contacts for the gate contact 1320, the source contacts 1318, and the drain contact 1322 can include a variety of different metals and alloys used to connect to the n-type and p-type GaN material. When a negative voltage is applied between the gate contact 1320 and the source contacts 1318, the depletion region extends into the n-type GaN channel layer 1112 along the side wall of the trench 1010.

In some embodiments, the formation of the gate contact 1320, the source contacts 1318, and the drain contact 1322 can include one or more annealing processes. The annealing process can include subjecting the vertical JFET to relatively high temperatures, up to 950° C. The annealing process may not affect the resistivity of the barrier region 906. In some examples, the resistivity properties of the barrier region 906 may improve after the annealing processes. In some embodiments, thermal annealing may be performed as a separate process after the formation of the barrier region 906, after the formation of either of the GaN channel layer 1112 and GaN gate layer 1114, or after the formation of the ohmic contacts.

In some embodiments, an encapsulation layer can be added to enclose the gate contact 1320 to isolate the gate contact 1320 from the source contacts 1318. The source contacts 1328 can be accessed by a source via provided by an interconnect metallization layer formed over the gate encapsulation, with access to the gate contact 1320 preserved in the direction into/out from the view shown in FIG. 13. The encapsulation layer may be a silicon nitride layer deposited using a plasma enhanced chemical vapor deposition process (PECVD). The interconnect metallization can be a gold plating layer.

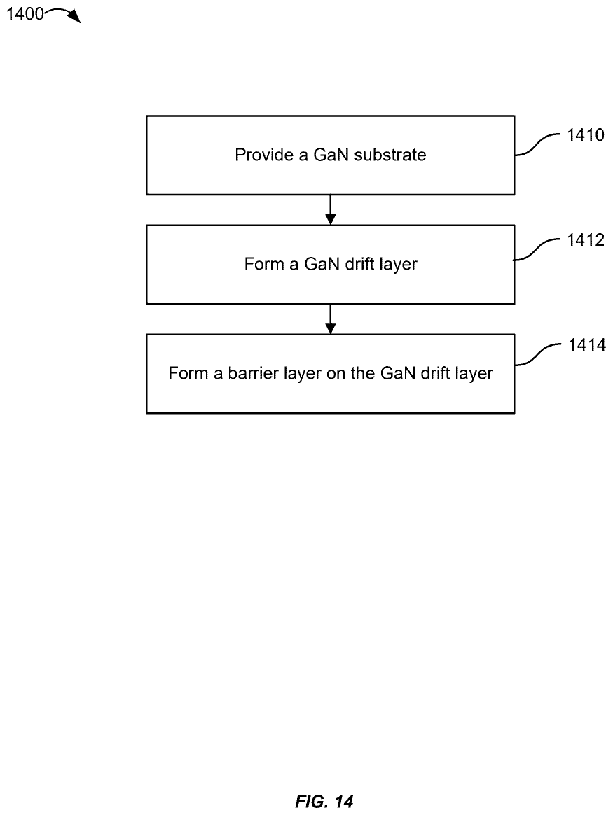

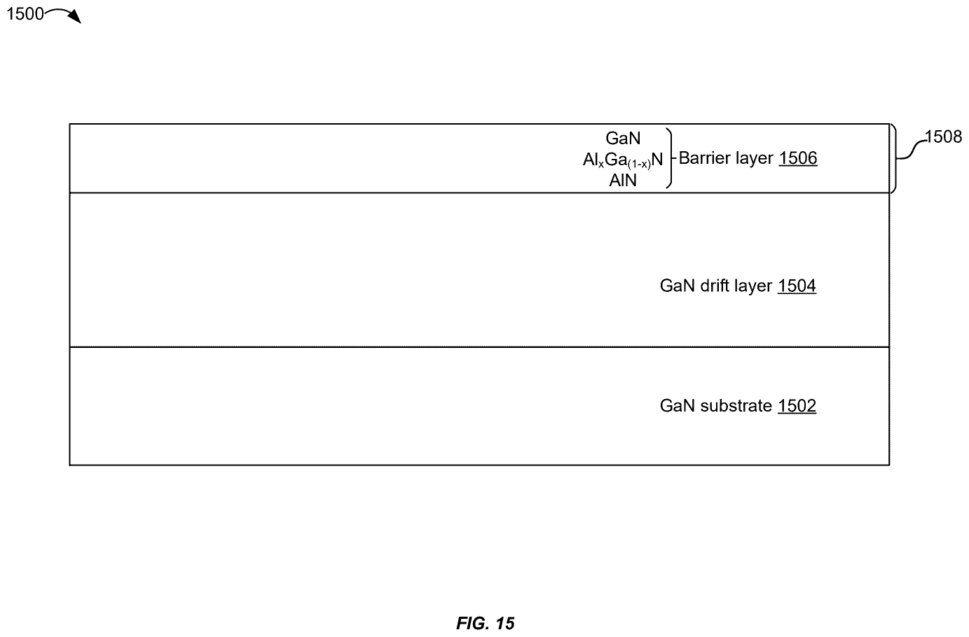

FIG. 14 is a simplified flowchart illustrating a method 1400 for making a GaN drift layer with an epitaxial barrier layer, according to some embodiments. FIG. 15 is a diagram illustrating a GaN drift layer 1504 and a barrier layer 1506, according to some embodiments. The GaN layers of FIG. 15 may be formed according to the method 1400 of FIG. 14.

The method 1400 includes providing (1410) a substrate. In typical embodiments, the substrate can be a GaN substrate 1502. The GaN substrate 1502 may be grown using a suitable growth process. The GaN substrate 1502 may be an N-type GaN substrate in some embodiments. The GaN substrate 1502 may be relatively thick, about 450 μm, but the thickness can depend on the size of the wafer. For example, a GaN substrate 1502 of 100 mm (~4 in) may have a thickness of about 450 μm, while a GaN substrate 1502 of 150 mm (~6 in) may have a thickness of about 550 μm. The GaN substrate 1502 may exhibit a resistivity of about 12 mΩ-cm² in certain embodiments.

The method 1400 also includes forming (1412) a drift layer on the GaN substrate 1502. The drift layer may also be a GaN drift layer 1504. The GaN drift layer 1504 may be epitaxially grown on the GaN substrate 1502. The GaN drift layer 1504 can be doped. The doping can be either n-type or p-type, according to some embodiments. The doping concentration of the GaN drift layer 1504 can be about 1×10¹⁶ cm⁻³ or less, depending on the breakdown voltage requirements of the device. In some embodiments, the GaN drift layer 1504 can be formed using hydride vapor phase epitaxy (HVPE) process. The deposited GaN drift layer 1504 may be about 3 μm to 50 μm thick. In some embodiments, the GaN drift layer 1504 can be formed using metalorganic chemical vapor deposition (MOCVD) process.

The method 1400 can also include forming (1414) a barrier layer 1506 on the drift layer 1504. The barrier layer 1506 can be epitaxially grown on the GaN drift layer 1504. In some embodiments, the barrier layer 1506 can be an epitaxial GaN barrier layer. In some embodiments, the barrier layer 1506 can be a graded epitaxial barrier layer that includes aluminum gallium nitride (AlGaN) and GaN. In a graded epitaxial barrier layer, the AlGaN can have proportionally more aluminum than gallium in a portion of the barrier layer 1506 close to the surface of the drift layer, with the proportion of aluminum decreasing in portions of the barrier layer 1506 away from the surface of the drift layer 1504. For example, the graded epitaxial barrier layer can include AlₓGa₍₁₋ₓ₎N for 0≤x≤1, with the amount x of aluminum about 1 at the surface of the drift layer (forming an aluminum nitride AlN layer), and the amount x of aluminum decreasing to about 0 at the surface of the barrier layer 1506 (forming a GaN layer). In some embodiments, the barrier layer can include more than one layer formed using an epitaxial growth process. For example, a first layer of the barrier layer 1506 can be epitaxially grown on the surface of the drift layer 1504 and can include AlN. A second layer can be epitaxially grown on the AlN layer and can include AlₓGa₍₁₋ₓ₎N, with x selected between 0 and 1. A third layer can be epitaxially grown on the AlₓGa₍₁₋ₓ₎N layer and can include GaN. Having GaN as the material at the surface of the barrier layer 1506 can improve the properties of subsequent regrowth GaN layers formed on the barrier layer.

In some embodiments, the barrier layer 1506 can be doped with elemental dopants to improve the resistivity of the barrier layer 1506. The dopants can include carbon, nickel, and/or iron dopants, in various embodiments. The dopants can be introduced in the epitaxial growth process used to form the barrier layer 1506. For example, a GaN barrier layer can be doped with nickel during epitaxial growth to form the barrier layer 1506. In various embodiments, the barrier layer 1506 including AlN and/or AlₓGa₍₁₋ₓ₎N can also be doped with carbon, nickel, and/or iron dopants.

The barrier layer 1506 can be formed using various epitaxial processes, including hydride vapor-phase epitaxy (HVPE) or metalorganic chemical vapor deposition (MOCVD). The epitaxial growth process can form a barrier layer 1506 with significantly higher resistivity than the underlying GaN drift layer 1504, allowing the barrier layer 1506 to withstand significant voltage difference across the source/drain of a JFET.

The barrier layer 1506 can be characterized by the following properties. The barrier layer 1506 can have a relatively high resistivity. For example, the barrier layer 1506 can be characterized by a resistivity of between about 10⁸ Ω/sq to about 10¹² Ω/sq. In some embodiments, the barrier layer has a resistivity of about 10¹² Ω/sq. The barrier layer 1506 can remain relatively stable within its resistivity range during subsequent processing steps. The barrier layer 1506 can withstand an applied voltage (e.g., a stand-off voltage) in a stable manner. The barrier layer 1506 should not adversely impact quality of subsequent epitaxial growth and not introduce deep level charge carrier traps that can inhibit dispersion characteristics of the device.

In some embodiments, a buffer layer can be formed on the drift layer. The buffer layer can include AlₓGa₍₁₋ₓ₎N. The aluminum composition of an AlₓGa₍₁₋ₓ₎N buffer layer can be 0.1≤x≤0.3. The buffer layer can be epitaxially grown using an HPVE, MOCVD, or MBE process. In some embodiments, the buffer layer can have a thickness of between about 10 nm to about 100 nm.

By forming the barrier layer 1506 on the GaN drift layer 1504, several advantages are achieved. First, the high resistivity barrier layer 1506 effectively serves to isolate the channel and source access regions from the drift regions of the device. Consequently, greater control over the channel dimensions and resistance can be achieved, which can be finely adjusted through the layer thicknesses and doping levels of the regrowth regions disposed on the barrier layer 1506. Furthermore, the barrier layer 1506 can be implemented in either patterned or non-patterned configurations, enabling use of this approach to realize both planar and side wall channel configurations. These configurations can result in device topologies with relaxed lateral dimension requirements, as well as relaxed lithography and etch requirement while also improving the operating parameters of the FET. The increased lateral dimension (e.g., width of the trench between source regions) can improve access to the source regions and/or gate regions for formation of source and/or gate contacts, which can improve contact resistance due to the greater contact area in those regions.

Because the barrier layer 1506 is epitaxially grown, tight controls on the thickness of the barrier layer 1506 are possible. In some embodiments, the barrier layer 1506 can have a thickness of between about 500 nm to about 4μm. The control of the thickness of the barrier layer 1506 can allow for precise control of the standoff voltage permitted by the barrier layer 1506, which in turn allows for improved conductivity control of the channel formed in the GaN regrowth layers on the barrier layer 1506. This results in improved control of the FET threshold voltage repeatability and uniformity and manufacturability of the FET device.

In addition, the fabrication of the barrier layer 1506 is suitable for both enhancement mode (e-mode) and depletion mode (d-mode) devices. If the channel conductivity is such that meaningful current flows from source to drain at zero (or slightly positive) gate bias, the device is d-mode. This mode is often referred to as “normally-on.” If the channel conductivity is such that no meaningful current flows from the source to drain at zero gate bias, the device is considered e-mode. This mode is often referred to as “normally-off.” Devices of either mode type can be achieved through judicious choice of doping levels and channel layer dimensions. A JFET is a common high-power transistor design that opens or closes the channel using the depletion region generated at the interface of an n-type and p-type material. A depletion region in a PN junction is a narrow area where mobile charge carriers (electrons and holes) have diffused away, leaving behind a region with only fixed ionized donor and acceptor atoms, creating an electric field across the junction. Essentially, it's a region depleted of free charge carriers due to diffusion of charges across the junction. As described below, the barrier layer 1506 allows for improved control of the channel region during fabrication of FET devices, including embodiments where the channel region forms a two-dimensional electron gas at an interface between GaN regrowth layers on the barrier layer 1506.

A further advantage of an epitaxially grown barrier layer 1506 is that it can provide enhanced latitude in the design of gate length within a vertical GaN junction field-effect transistor (JFET) architecture. By virtue of improved electrostatic control, the device can tolerate a broader range of gate lengths without compromising on-resistance or breakdown performance. This flexibility allows a longer gate length to be selected to improve electrostatic isolation between the gate-controlled channel and the drain-side depletion region under high drain bias. A longer gate length increases the physical separation between the source-side pinch-off point and the influence of the drain electric field, thereby reducing effects such as drain-induced barrier lowering (DIBL) and mitigating punch-through effects. The resulting structure maintains a more stable channel potential at elevated drain voltages, providing improved threshold-voltage stability, reduced subthreshold leakage, and enhanced ruggedness against high-field turn-on events. Consequently, the embodiments described herein enable an optimized balance between conduction efficiency and high-voltage reliability that is not attainable in some conventional GaN JFET designs.

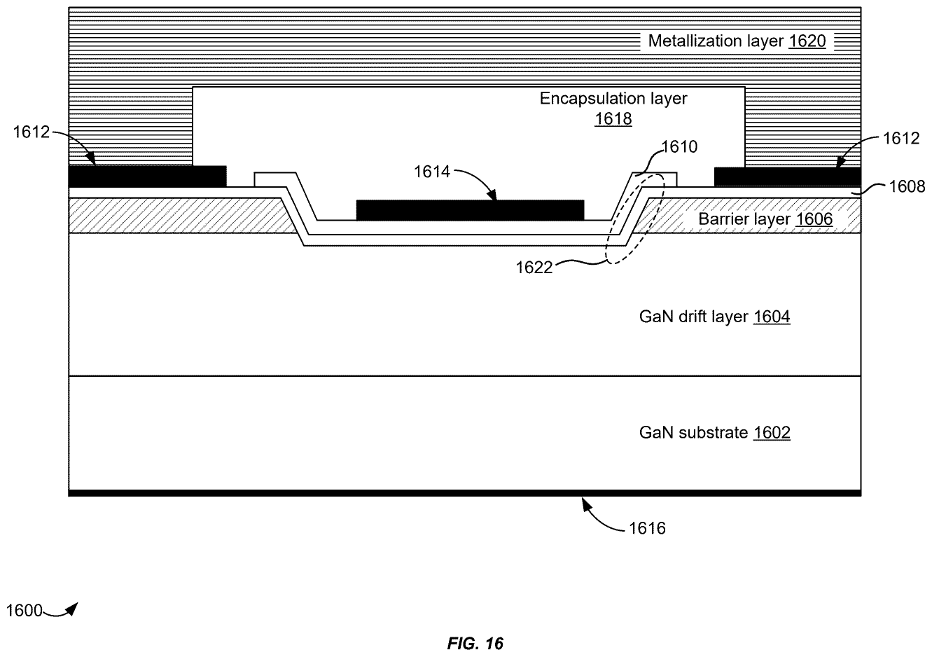

FIG. 16 is a diagram illustrating a cross section view of a vertical GaN junction field effect transistor (JFET) 1600 having an epitaxial barrier layer 1606, according to some embodiments. The vertical GaN JFET can include a GaN substrate 1602, a GaN drift layer 1604, and a barrier layer 1606. The GaN substrate 1602, GaN drift layer 1604, and barrier layer 1606 may be examples of GaN substrate 1502, GaN drift layer 1504, and barrier layer 1506, respectively, that are described above with respect to FIG. 15.

The vertical GaN JFET 1600 can include a channel layer 1608 formed on the barrier layer and a portion of the GaN drift layer 1604. The channel layer 1608 can be an n-type GaN channel layer. The channel layer 1608 can be moderately doped. For example, the channel layer 1608 can have a dopant concentration of 1×10¹⁶ cm⁻³. In some examples, the dopant concentration may be between about 1×10¹⁶ cm⁻³ and 1×10¹⁸ cm⁻³. The channel layer 1608 thickness can be about 200 nm, in an example. In some examples the channel layer 1608 can have a thickness of about 100 nm to about 500 nm. The doping concentration and the thickness can be controlled (in conjunction with the doping concentration and thickness of the gate layer 1610) so that the channel region of the JFET operates correctly (e.g., fully depleted of charge carriers at no applied gate potential).

The vertical GaN JFET 1600 can include a gate layer 1610 formed on the channel layer 1608. The gate layer 1610 may be a highly doped p-type GaN gate layer. The gate layer 1610 can have a dopant concentration of about 1×10¹⁹ cm⁻³, in an example. In some examples, the gate layer 1610 can have a dopant concentration of between about 1×10¹⁷ cm⁻³ and 1×10¹⁸ cm⁻³. The gate layer 1610 can have a thickness of 500 nm, in an example. In some examples, the thickness of the gate layer 1610 can be between about 100 nm to about 500 nm. As with the channel layer 1608, the doping and thickness of the GaN gate layer 1610 can be controlled to support the designed operation of the JFET.

The channel layer 1608 and the gate layer 1610 may be formed using molecular beam epitaxy (MBE) or metalorganic chemical vapor deposition (MOCVD). Advantages of using MBE to grow the channel layer 1608 and/or the gate layer 1610 include that the lower temperatures of the MBE process (less than 800° C.) can preserve the high resistive properties of the barrier layer 1606.

The vertical GaN JFET 1600 can also include source contacts 1612 disposed on the sides of a trench including a gate contact 1614, forming source regions and gate regions of the vertical GaN JFET 1600. A drain contact 1616 can be formed on the backside of the GaN substrate 1602 (forming a vertical JFET). The arrangement of source contacts 1612 and drain contact 1616 on the GaN substrate 1602 results in a current path vertically through the GaN drift layer 1604, thereby forming a vertical JFET. In this embodiment, a channel 1622 is formed along the vertical side wall, and may be vertical (or nearly vertical). In some embodiments, the channel 1622 can include the interface between a GaN channel layer 1608 and an AlₓGa₍₁₋ₓ₎N gate layer 1610, forming a two-dimensional electron gas (2DEG) during operation of the device (a vertical GaN FET).

The source, gate, and drain contacts can be ohmic contacts. In some embodiments, the ohmic contacts are formed by a metal deposition process. The ohmic contacts for the gate contact 1614, the source contacts 1612, and the drain contact 1616 can include a variety of different metals and alloys used to connect to the n-type and p-type GaN material. When a negative voltage is applied between the gate contact 1614 and the source contacts 1612, the depletion region extends into the n-type GaN channel layer 1608 along the side wall of the trench in the channel 1622.

In some embodiments, the formation of the gate contact 1614, the source contacts 1612, and the drain contact 1616 can include one or more annealing processes. The annealing process can include subjecting the vertical JFET to relatively high temperatures, up to 950° C. The annealing process may not affect the resistivity of the barrier layer 1606. In some examples, the resistivity properties of the barrier layer 1606 may improve after the annealing processes. In some embodiments, thermal annealing may be performed as a separate process after the formation of the barrier layer 1606, after the formation of either of the GaN channel layer 1608 and GaN gate layer 1610, or after the formation of the ohmic contacts.

In some embodiments, the vertical GaN JFET 1600 can include an encapsulation layer 1618 enclosing the gate contact 1614 to isolate the gate contact 1614 from the source contacts 1612. The source contacts 1612 can be accessed by a source via provided by an interconnect metallization layer 1620 formed over the encapsulation layer 1618, with access to the gate contact 1614 preserved in the direction into/out from the view shown in FIG. 16. The encapsulation layer 1618 may be a silicon nitride layer deposited using a plasma enhanced chemical vapor deposition process (PECVD). The interconnect metallization layer 1620 can be a gold plating layer.

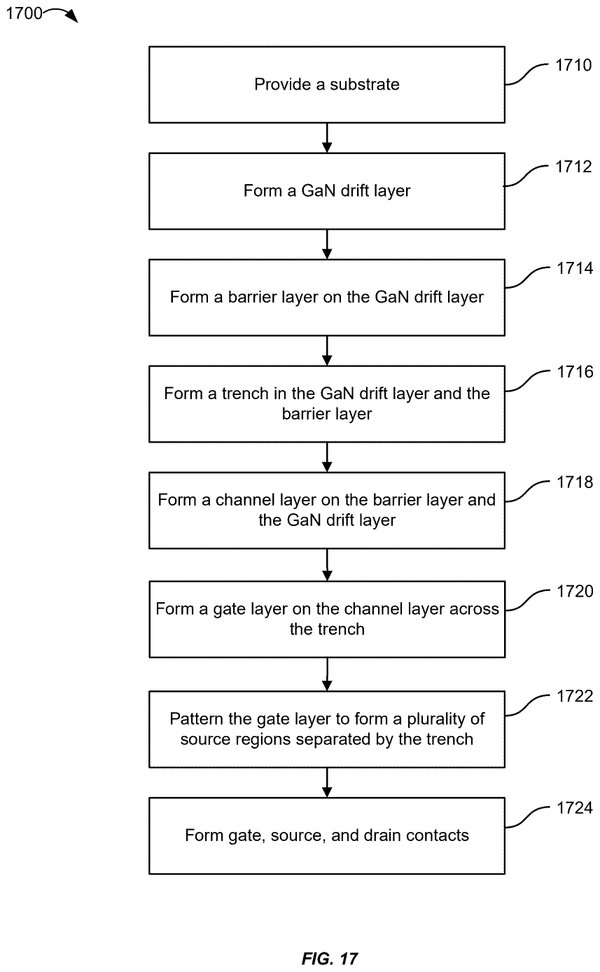

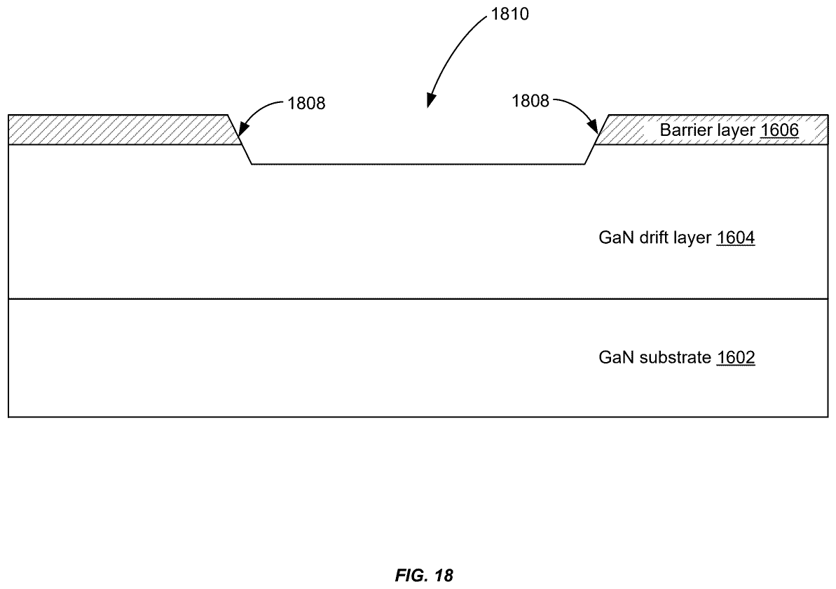

FIG. 17 is a simplified flowchart illustrating a method 1700 for making a vertical GaN JFET having a vertical side wall trench and an epitaxial barrier layer, according to some embodiments. FIGS. 18-21 are diagrams illustrating cross-section views of the vertical GaN JFET at various steps of the method of FIG. 17.

The method 1700 can include providing a substrate (1710), forming a drift layer GaN (1712), and forming a barrier layer on the drift layer (1714). Referring to FIG. 18, the substrate may be a GaN substrate 1602, the drift layer may be a GaN drift layer 1604, and the barrier layer 1606 may be an epitaxially grown layer of high-resistivity material on the GaN drift layer 1604.

The barrier layer 1606 can be epitaxially grown on the GaN drift layer 1604. As described above with respect to FIGS. 14 and 15, in some embodiments, the barrier layer 1606 can be an epitaxial GaN barrier layer. In some embodiments, the barrier layer 1606 can be a graded epitaxial barrier layer that includes aluminum gallium nitride (AlGaN) and GaN. In a graded epitaxial barrier layer, the AlGaN can have proportionally more aluminum than gallium in a portion of the barrier layer 1606 close to the surface of the drift layer, with the proportion of aluminum decreasing in portions of the barrier layer 1606 away from the surface of the drift layer 1604. For example, the graded epitaxial barrier layer can include AlₓGa₍₁₋ₓ₎N for 0≤x≤1, with the amount x of aluminum about 1 at the surface of the drift layer (forming an aluminum nitride AlN layer), and the amount x of aluminum decreasing to about 0 at the surface of the barrier layer 1606 (forming a GaN layer). In some embodiments, the barrier layer can include more than one layer formed using an epitaxial growth process. For example, a first layer of the barrier layer 1606 can be epitaxially grown on the surface of the drift layer 1604 and can include AlN. A second layer can be epitaxially grown on the AlN layer and can include AlₓGa₍₁₋ₓ₎N, with x selected between 0 and 1. A third layer can be epitaxially grown on the AlₓGa₍₁₋ₓ₎N layer and can include GaN. Having GaN as the material at the surface of the barrier layer 1606 can improve the properties of subsequent regrowth GaN layers formed on the barrier layer.

The structure of the vertical JFET with vertical side wall channel 1622 can allow for the formation of the barrier layer 1606 extending over the entirety of the GaN drift layer 1604. The subsequent processing steps can isolate different devices constructed on the GaN drift layer 1604 and GaN substrate 1602 by, for example, forming implantation regions on the edges of the devices.

The method 1700 can also include forming a trench 1810 in the drift layer (1716). Referring to FIG. 18, the trench 1810 may be formed through the barrier layer 1606 into the GaN drift layer 1604, extending below the interface between the GaN drift layer 1604 and the epitaxially grown barrier layer 1606. The trench 1810 may be formed by an etching process like inductively coupled plasma (ICP) etching. The trench 1810 can have vertical side walls 1808 that define the sides of the trench 1810. As shown in FIG. 18, the vertical side walls 1808 may be sloped. The angle of the slope of the vertical side walls 1808 may be varied based on the design of the JFET. In some embodiments, the vertical side walls 1808 may be vertical or nearly vertical.

The formation of the trench 1810 may expose the barrier layer 1606 at the vertical side walls 1808. The trench 1810 may be etched deeper into the GaN drift layer 1604 than the vertical extent of the barrier layer 1606, so that the region in the middle of the trench is exposed material of the GaN drift layer 1604 and not material of the barrier layer 1606. The trench 1810 can separate the surface of the GaN drift region 1604 into two lateral regions on either side of the trench 1810.

In some embodiments, the surface of the GaN drift layer 1604 and the barrier layer 1606 can be cleaned and prepped using suitable solvents (e.g., tetramethylammonium hydroxide, piranha solvent) after formation of the trench 1810 and prior to the subsequent regrowth process.

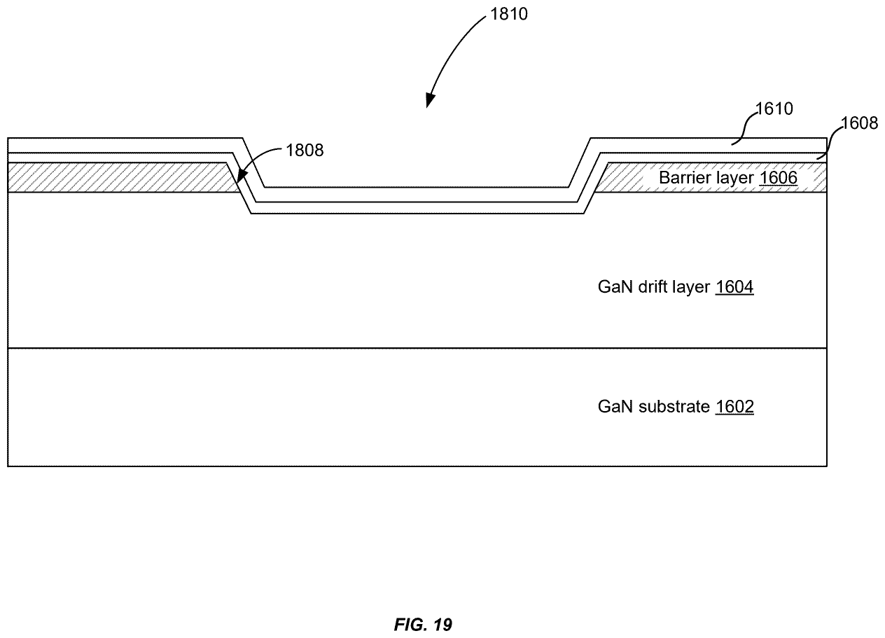

The method 1700 can also include forming a channel layer (1718) on the exposed GaN drift layer 1604 in the trench 1810 and the barrier layer 1606. As shown in FIG. 19, the channel layer 1608 can be formed on the barrier layer 1606 on the lateral portions of the barrier layer 1606 that are on either side of the trench 1810, with the channel layer 1608 extending along the vertical side walls 1808 and onto the GaN drift layer 1604 in the trench 1810.

The method 1700 can also include forming a gate layer (1720) on the channel layer. As shown in FIG. 19, the gate layer 1610 can extend along the channel layer 1608 along the vertical side wall 1808 and the trench 1810. As described above with respect to FIG. 16, in some embodiments the channel layer 1608 may be an n-type GaN channel layer and the gate layer 1610 may be a p-type GaN gate layer. Both the channel layer 1608 and the gate layer 1610 can be formed by an regrowth process using molecular beam epitaxy (MBE) or metalorganic chemical vapor deposition (MOCVD), in some embodiments.

In some embodiments, an etch stop can be disposed between the channel layer 1608 and the gate layer 1610 during the growth processes of those layers. The etch stop can preserve the well-controlled thickness of the channel layer 1608 that was formed first, particularly in the source access and contact regions of the device. After patterning the gate layer 1610, the etch stop can be removed from the exposed regions of the channel layer 1608. The presence of an etch stop between the source structures and the channel layer 1608 may not negatively impact the performance of the resulting JFET since no gate current should flow through the gate structure.

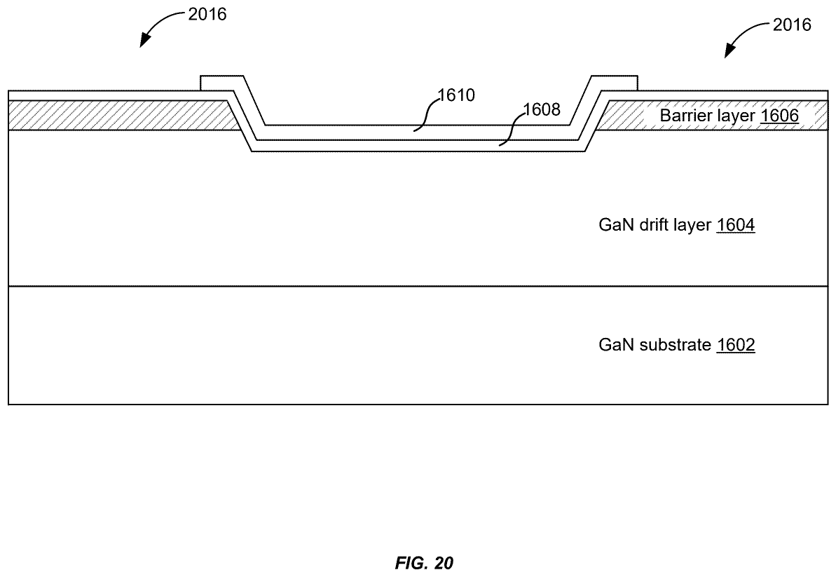

The method 1700 can also include patterning the gate layer to form a plurality of source regions (1722). Referring to FIG. 20, the plurality of source regions 2016 can be formed on each side of the trench 1810. Patterning the gate layer 1610 to form the plurality of source regions 2016 can include etching the gate layer 1610 to remove the gate layer 1610 down to the channel layer 1608. The etching may be an inductively coupled plasma (ICP) dry etching process. As described above, in some embodiments, an etch stop can be disposed between the channel layer 1608 and the gate layer 1610 during the growth processes of those layers.

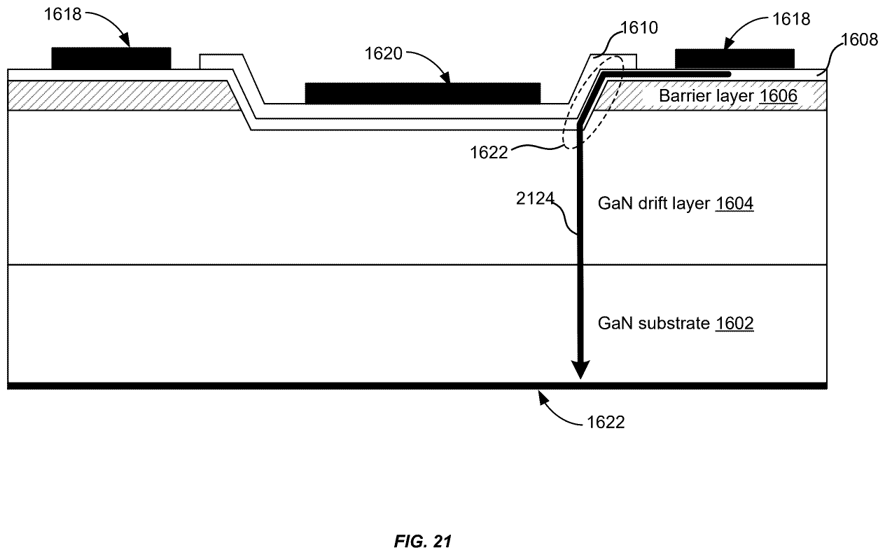

The method 1700 can also include forming gate, source, and drain contacts (1724). Referring now to FIG. 21, gate contact 1620 can be formed in the trench 1810 on the gate layer 1610. A plurality of source contacts 1618 can be formed in the source regions 2016 on the surface of the channel layer 1608. A drain contact 1622 can be formed on the backside of the GaN substrate 1602 (forming a vertical JFET). The arrangement of source contacts 1618 and drain contact 1622 on the GaN substrate 1602 results in a current path 2124 vertically through the GaN drift layer 1604 as shown, thereby forming a vertical JFET. In this embodiment, the channel 1622 is formed along the vertical side wall, and may be vertical (or nearly vertical).

Where terms are used without explicit definition, it is understood that the ordinary meaning of the word is intended, unless a term carries a special and/or specific meaning in the field of semiconductor devices and device manufacturing or other relevant fields. The terms “about” or “substantially” are used to indicate a deviation from the stated property or numerical value within which the deviation has little to no influence of the corresponding function, property, or attribute of the structure being described. In an illustrated example, where a dimensional parameter is described as “substantially equal” to another dimensional parameter, the term “substantially” is intended to reflect that the two dimensions being compared can be unequal within a tolerable limit, such as a fabrication tolerance. Similarly, where a geometric parameter, such as an alignment or angular orientation, is described as “about” normal, “substantially” normal, “substantially” parallel, “nearly” vertical, the terms “about” or “substantially,” and “nearly” are intended to reflect that the alignment or angular orientation can be different from the exact stated condition (e.g., not exactly normal) within a tolerable limit. For dimensional values, such as diameters, lengths, widths, or the like, the term “about” can be understood to describe a deviation from the stated value of up to ±10%. For example, a dimension of “about 10 nm” can describe a dimension from 9 nm to 11 nm.

It should be appreciated that the specific steps illustrated in FIGS. 3, 8, & 17 provide particular methods of fabricating a vertical GaN JFET according to embodiments of the present invention. Other sequences of steps may also be performed according to alternative embodiments. For example, alternative embodiments of the present invention may perform the steps outlined above in a different order. Moreover, the individual steps illustrated in FIGS. 3, 8, & 17 may include multiple sub-steps that may be performed in various sequences as appropriate to the individual step. Furthermore, additional steps may be added or removed depending on the particular applications. One of ordinary skill in the art would recognize many variations, modifications, and alternatives.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A field effect transistor comprising:
a substrate;
a drift layer coupled to the substrate, wherein the drift layer comprises an interface and a barrier region disposed within the drift layer at a location between the interface and the substrate;
a channel layer coupled to the drift layer at the interface;
a gate layer coupled to the channel layer;
a source contact electrically connected to the channel layer;
a gate contact electrically connected to the gate layer; and
a drain contact electrically connected to the substrate.

2. The field effect transistor of claim 1, wherein the location of the barrier region is about 10 nm below the interface of the drift layer.

3. The field effect transistor of claim 1, wherein the barrier region extends from about 1 nm below the interface of the drift layer to about 100 nm below the interface of the drift layer.

4. The field effect transistor of claim 1, wherein the barrier region is formed by ion implantation.

5. The field effect transistor of claim 4, wherein the ion implantation comprises argon ions or nitrogen ions.

6. The field effect transistor of claim 1, wherein the barrier region comprises a higher resistivity than the drift layer.

7. The field effect transistor of claim 1, wherein the channel layer forms a channel disposed laterally between the gate layer and the barrier region.

8. The field effect transistor of claim 1, wherein the drift layer comprises an n-type GaN layer characterized by a doping concentration of about 1×10¹⁶ cm⁻³.

9. The field effect transistor of claim 1, wherein the drift layer has a thickness of from about 10 μm to about 25 μm.

10. The field effect transistor of claim 1, wherein the barrier region comprises a lateral edge within the drift layer, wherein the gate layer overlaps the lateral edge by a distance between about 0.1 μm to about 10 μm.

11. The field effect transistor of claim 1, wherein the channel layer comprises an epitaxial n-type GaN layer, and wherein the gate layer comprises an epitaxial p-type GaN layer.

12. A method comprising:
providing a substrate;
forming a gallium nitride (GaN) drift layer on the substrate, the GaN drift layer comprising a surface opposite an interface with the substrate;
forming a barrier region within the GaN drift layer at a location between the surface and the substrate;
forming a channel layer on the surface of the GaN drift layer;
forming a gate layer on the channel layer;
patterning the gate layer to form a plurality of gates separated by a channel; and
forming gate contacts on the plurality of gates, a source contact on the channel, and a drain contact on the substrate.

13. The method of claim 12, wherein forming the barrier region within the GaN drift layer comprises forming the barrier region using ion implantation.

14. The method of claim 12, wherein the location of the barrier region is about nm below the surface of the drift layer.

15. The method of claim 12, wherein the barrier region extends from about nm below the interface of the drift layer to about 100 nm below the surface of the drift layer.

16. The method of claim 12, further comprising forming a protection layer on the surface of the drift layer prior to forming the barrier region at the location in the drift layer.

17. The method of claim 12, wherein forming the channel layer comprises performing a regrowth process to regrow an n-type GaN channel layer.

18. The method of claim 12, wherein forming the gate layer comprises performing a regrowth process to regrow a p-type GaN gate layer.

19. The method of claim 18, wherein the regrowth process comprises a molecular beam epitaxy (MBE) process characterized by a growth temperature of less than about 800° C.

20. The method of claim 12, wherein forming the gate contacts and the source contact comprises a thermal annealing characterized by an annealing temperature of less than about 950° C., and wherein the thermal annealing preserves the barrier region in the GaN drift layer.
